(19) United States
(12) Patent Application Publication
(10) Pub. No.: US 2018/0311877 A1
(43) Pub. Date: Nov. 1, 2018

(54) NANOINJECTION MOLDING

(71) Applicants: AGENCY FOR SCIENCE, TECHNOLOGY AND RESEARCH, Singapore (SG); BANSHING INDUSTRIAL PTE LTD, Singapore (SG)

(72) Inventors: Mohamed Sultan Mohiddin SAIFULLAH, Singapore (SG); Siew Ling Karen CHONG, Singapore (SG); Yee Chong LOKE, Singapore (SG); Alvin CHENG, Singapore (SG); Nicholas LEONG, Singapore (SG)

(21) Appl. No.: 15/772,042

(22) PCT Filed: Oct. 27, 2016
(86) PCT No.: PCT/SG2016/050527

§ 371 Date: Apr. 27, 2018

(30) Foreign Application Priority Data
Oct. 27, 2015 (SG) 10201508851T

(51) Int. Cl. B29C 45/37; B81C 99/00; C23C 14/14; C23C 14/34; C25D 1/10; G03F 7/00

(52) U.S. Cl. CPC B29C 45/37; B81C 99/009; C23C 14/14; B82Y 40/00; C25D 1/10; G03F 7/0002; B81C 2201/0153; C23C 14/34

(57) ABSTRACT

An injection mold insert with hierarchical structures and a method for method of making such injection mold inserts are provided. The method includes imprinting a primary imprint structure on an article and imprinting a secondary imprint structure on the primary imprint structure on the article. The secondary imprint structure includes a plurality of shapes, each of the plurality of shapes being substantially smaller than shapes of the primary imprint structure. The method further includes bonding the article to a substrate, sputter-coating the article with a metal film as an electroforming seed layer, and electroforming the injection mold insert over the article. Finally, the method includes dissolving the article to define the injection mold insert having a negative replica of the primary and secondary imprint structures.

### PRIORITY CLAIM

This application claims priority from Singapore Patent Application No. 10201508851T filed on 27 Oct. 2015.

### TECHNICAL FIELD

The present invention generally relates to methods for fabricating injection mold inserts and inserts fabricated by such methods, and more particularly relates to methods for fabricating injection mold inserts for forming nanoscale surface textures onto the injection-molded products.

### BACKGROUND OF THE DISCLOSURE

Injection molding is a well-established commercial process used for the manufacture of parts or components from thermoplastic and thermosetting materials. A typical injection molding process consists of the material to be molded being fed into the hopper. The hopper typically leads to a heated barrel reciprocated by a rotating screw that feeds the material into the molds through pre-defined gates and runners. The pressure, temperature and holding times can be optimized to enable a specific molding criterion to be fulfilled.

For injection molding, the mold or insert are usually made from hardened steel, aluminum or copper alloys to enable the inserts to withstand the injection molding process conditions. The inserts are usually machined via a computer numerical controlled (CNC) machine or using an electrical discharge machine (EDM).

While injection molding is extremely competitive to other fabrication techniques, the process itself still suffers from inherent limitations when the desired resolution of the parts and components to be produced is in the micrometer range and below. While there have been efforts to carry out molding in the nanorange, this is still limited to components.

Thus, what is needed is a method of fabricating injection mold inserts that yields nanoscale surface textures onto the injection-molded products. Furthermore, other desirable features and characteristics will become apparent from the subsequent detailed description and the appended claims, taken in conjunction with the accompanying drawings and this background of the disclosure.

### SUMMARY

According to at least one embodiment of the present invention, a method of making an injection mold insert with hierarchical structures is provided. The method includes imprinting a primary imprint structure on an article and imprinting a secondary imprint structure on the primary imprint structure on the article. The secondary imprint structure includes a plurality of shapes, each of the plurality of shapes being substantially smaller than shapes of the primary imprint structure. The method further includes bonding the article to a substrate, sputter-coating the article with a metal film as an electroforming seed layer, and electroforming the injection mold insert over the article. Finally, the method includes dissolving the article to define the injection mold insert having a negative replica of the primary and secondary imprint structures.

### BRIEF DESCRIPTION OF THE DRAWINGS

The accompanying figures, where like reference numerals refer to identical or functionally similar elements throughout the separate views and which together with the detailed description below are incorporated in and form part of the specification, serve to illustrate various embodiments and to explain various principles and advantages in accordance with a present embodiment.

FIG. 1 depicts a planar view of a conventional injection molding machine.

FIG. 2, comprising FIGS. 2A and 2B, depicts side planar views of a hierarchical template formed during a process flow for making the hierarchical structures in accordance with a present embodiment, wherein FIG. 2A depicts a first imprinting to form primary hierarchical structures of an array of a micro lens and FIG. 2B depicts a second imprinting to form secondary hierarchical structures on the primary hierarchical structures.

FIG. 3, comprising FIGS. 3A and 3B, depicts scanning electron microscope (SEM) views of the hierarchical structures fabricated in the process of FIG. 2 in accordance with the present embodiment, wherein FIG. 3A depicts an imprinted polymer template and FIG. 3B depicts a corresponding nickel replica insert.

FIG. 4, comprising FIGS. 4A, 4B and 4C, depicts side planar views of a nickel insert formed during a process flow for insert fabrication in accordance with the present embodiment, wherein FIG. 4A depicts spin coating SU8 on a silicon substrate as a bonding adhesive for the template, FIG. 4B depicts the SU8 bonding process, and FIG. 4C depicts electroforming a sputtered conductive seed layer to form the nickel insert.

FIG. 5, comprising FIGS. 5A and 5B, depicts SEM views of nickel inserts with anti-reflection structures fabricated by the process of FIG. 4 in accordance with the present embodiment, wherein FIG. 5A is a top planar view and FIG. 5B is a tilted view.

FIG. 6 depicts views of dual nickel inserts fabricated in accordance with the present embodiment and mounted in molding jigs for injection molding operations.

FIG. 7, comprising FIGS. 7A, 7B and 7C, depicts SEM views of injection molded anti-reflection structures molding using nickel inserts fabricated in accordance with the present embodiment, wherein FIG. 7A is a top planar view, FIG. 7B is a tilted view, and FIG. 7C is a further magnified tilted view.

FIG. 8 depicts a view of visual inspection of the injection molded anti-reflection structures of FIG. 7 in accordance with the present embodiment.

And FIG. 9 is a graph depicting transmissive properties of injection molded lenses prepared at various experimental conditions in accordance with the present embodiment.

Skilled artisans will appreciate that elements in the figures are illustrated for simplicity and clarity and have not necessarily been depicted to scale.

### DETAILED DESCRIPTION

The following detailed description is merely exemplary in nature and is not intended to limit the invention or the application and uses of the invention. Furthermore, there is no intention to be bound by any theory presented in the preceding background of the invention or the following detailed description. It is the intent of the present embodiment to present a process called nanoinjection molding to carry out transfer of nanometer-scale patterning onto injected molded products using inserts containing nanometer-sized features. The injection molding inserts fabricated in accordance with a present embodiment were modified with hybrid nanoimprinted templates to enable the nanoinjection molding process. The template can be a basic nanoimprinted structure such as pillars or an array of nanocone structures or a complex three-dimensional hierarchical structure. These structures are replicated onto a nickel insert in accordance with the present embodiment which, after the injection molding process, are a part of the overall macro injection molding product.

The inserts can either be single-sided and attached to a cavity side of a molding jig or double-sided where a core side of the molding jig and the cavity side of the molding jig has the nickel inserts attached thereto. This will then generate an injection-molded sample that can have nanostructures either on one or both sides of a molded polymer.

Nanoinjection molding in accordance with the present embodiment can be used for the molding of various products where micro and nanostructuring are required for the generation of specific functionalities. Examples include optical lens or helmet visors, which have either one or both sides covered with an array of nanometer cone structures that can greatly enhance the functionality by providing high clarity, anti-ultraviolet (UV) transmission and superior anti-glare.

Fabrication in accordance with the present embodiment targets a current gap in the injection molding market—the ability to form multiscale functionalities with high resolutions below two micrometers on injection molded products or parts using modified inserts. The fabrication process in accordance with the present embodiment focuses on modification of injection molding inserts leading to novel inserts which can impart features below two micrometers onto injection-molded products or parts. This will enable the creation of functionalities onto free-form three-dimensional products: functionalities such as anti-reflectivity (AR), which was selected for fabrication in accordance with the present embodiment due to the complexity and high resolution of the structures. Other functionalities that can be fabricated via the injection molding process in accordance with the present embodiment include anti-fog, anti-UV transmission, hydrophobicity, iridescence, antibacterial and may be extended to various other functionalities and combination of functionalities. Novel inserts fabricated in accordance with the present embodiment are critical to the nanoinjection molding process. An injection molding jig includes an injection molding insert such as a hybrid insert fabricated from nanoimprinting in accordance with the present embodiment. The hybrid inserts are preferably made from electroformed nickel and coated with iridium. Nickel and iridium are used to achieve an optimal combination of mechanical properties such as hardness and wear resistance desired in the injection molding process. The process is not exclusive to hybrid molds comprised of a combination of materials. For example, nickel molds can be used in the inserts provided the injection molding process conditions are suitably adjusted.

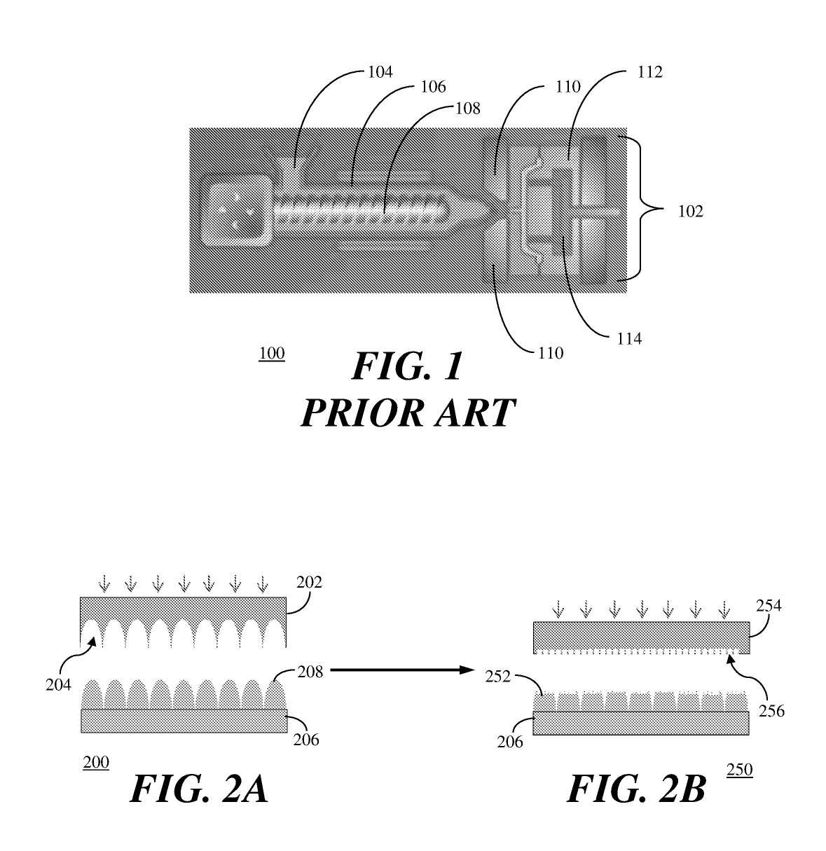

Referring to FIG. 1, a planar view 100 depicts a conventional injection molding machine 102. The machine 102 includes a hopper 104 coupled to a heated barrel 106 and a rotating screw 108, the rotating screw feeding the material to be molded from the hopper 104 through pre-defined gates and runners 110 to the mold 112 which includes a mold insert 114. A typical injection molding process consists of the material to be molded being fed into the hopper 104. The hopper 104 typically leads to the heated barrel 106 reciprocated by the rotating screw 108 that feeds the material into the mold 112 through the pre-defined gates and runners 110. The pressure, temperature and holding times are optimized to enable a specific molding criterion to be fulfilled. For conventional injection molding, the mold 112 and/or the mold inserts 114 are typically made from hardened steel, aluminum or copper alloys to enable the inserts 114 and the mold 112 to withstand the injection molding process conditions. The inserts 114 are usually machined via a computer numerical controlled (CNC) machine or using an electrical discharge machine (EDM). Using the insert 114, the injection molding machine 102 is able to produce numerous copies of a product, and these copies are termed “shots”.

Referring to FIGS. 2 to 5, a novel process for fabrication of nickel mold inserts with microstructures and nanostructures in accordance with a present embodiment using nanoimprint technology is described. The pattern transfer is essentially from an imprinted polymer that can be used as a platform template to be electroformed into a thick nickel mold. The process in accordance with the present embodiment relies on novel lamination and planarization methods that flatten and bond a soft template with patterns on its surface to a highly flat solid surface, typically a silicon wafer, without damage or physical contact to the patterns. In this manner, any complex feature such as moth's eye or hierarchical structures can be translated and replicated onto a nickel mold with a good uniform flatness. Therefore, the textured surface technology of nanoimprinting which can produce functional properties such as anti-wetting, super-hydrophobicity and anti-reflection can be translated onto nickel inserts in accordance with the present embodiment, thereby bringing forth a new dimension of producing biomimetic structures onto a three-dimensional scale by injection molding.

Mold replication from templates is needed to produce functional surfaces at industrially relevant throughput. In mold replication, it is important that the template used is extremely flat and uniform. Without this, misalignment, defects, breakage and low fidelity of replicated mold structures ultimately cannot provide the desired surface functions. The fabrication method in accordance with the present embodiment overcomes challenges in soft mold replication leading to fabrication of high quality robust and reusable inserts for injection molding. This method advantageously utilizes a spin-coated epoxy based intermediate layer to laminate a soft mold/template onto a silicon wafer. To ensure a highly conformal contact with the wafer, an epoxy glue is diluted and spin-coated with optimized thickness to provide strong bonding as well as flatness. The final assembly is sputter-coated by a thin metal film used as a seed layer or subsequent electroplating to fabricate a high quality nickel mold insert consisting of a negative replica of the template patterns with superior physical characteristics of flatness, smoothness, uniformity and high fidelity.

For simple structures such as pillars, holes or conical structures, replication has been previously carried out by direct nanoimprinting from a master mold. However, to make a complex hierarchical imprinted template, the present embodiment uses a dual-stage imprinting to form primary and secondary structures, such as a nanopillar on a lens structure.

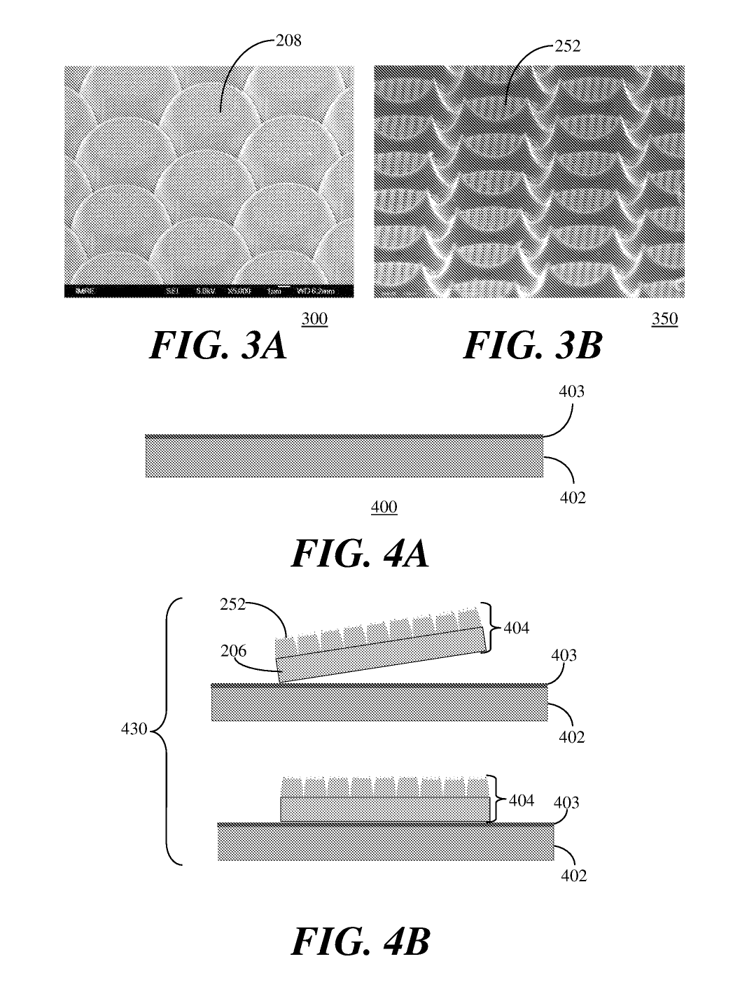

To prepare a template with hierarchical structures, two stages of sequential nanoimprinting are utilized to form the primary (micron-scale) and secondary (nanoscale) imprint structures at two non-planar levels onto a thin sheet of polycarbonate (PC) over large areas. Referring to FIG. 2, comprising FIGS. 2A and 2B, side planar views 200, 250 depict preparation of the PC template with hierarchical structures in accordance with a present embodiment. In a first step, the view 200 depicts a silicon mold 202 with a close pack array of micro lens 204 with diameters of 7.8 μm, pitch of 7.8 μm and a height of 5.5 μm imprinted onto a 250 μm thin polycarbonate (PC) sheet 206 to form the primary structures 208 which have a semi-cone shape. The imprinting is done at a temperature of 180° C. and a pressure of 40 bar pressure for 300 seconds. FIG. 3A depicts a scanning electron microscope (SEM) view 300 of an imprinted profile of the hierarchical structures 208 fabricated on the PC sheet 206 in accordance with the present embodiment.

Referring to FIG. 2B, the planar view 250 depicts secondary structures 252 being formed using another silicon mold 254 that has an array of 300 nm square holes 256 with an aspect ratio of one and a pitch size of 600 nm. The imprinted version of PC sheet 206 in this case is a hierarchical structure where the secondary features 252 are 300 nm square pillars as shown in the SEM image 350 of FIG. 3B. This imprinting is done at the condition of 150° C. at 20 bar pressure and a duration of 300 seconds.

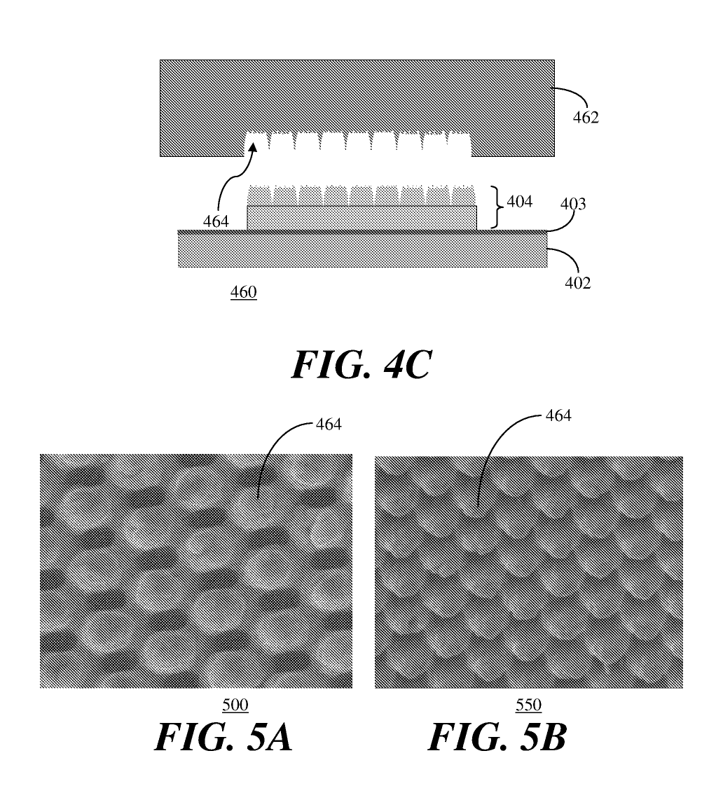

Referring to FIG. 4, comprising FIGS. 4A, 4B and 4C, side planar views 400, 430, 460 of a nickel insert formed during a process flow for insert fabrication in accordance with the present embodiment are depicted. As shown in the side planar view 400, a very smooth silicon substrate 402 is provided spin coating with an adhesive 403, such as SUB, as a bonding adhesive for the template. Referring to the side planar view 430, the bonding process in accordance with the present embodiment flatly glues the imprinted PC sheet onto the silicon substrate 402.

The imprinted PC film 404 with hierarchical structures resembles the as-received polymer film with similar flexibility and non-uniformity. Therefore, if it is used for electroforming of a nickel mold, it may result in a non-uniform wavy mold with misalignment of the structures on its surface. In order to have good fidelity of the nickel replica, the imprinted PC template must maintain a high degree of flatness throughout the whole electroforming process.

As the conditions of the nickel electrolyte during electroforming are constantly maintained at an acidic level and a high temperature of over 50° C. over a long period, it is essential that the whole assembly of the PC film 404 is strongly bonded onto the highly flat surface of the silicon wafer 402, is gap free and must be able to withstand the bath conditions while maintaining the flatness. The PC film 404 is assembled onto the wafer with an adhesive 403 such as SU8 in processing conditions defined by the adhesive.

Referring to FIG. 4C, the side planar view 460 depicts electroforming of a nickel mold 462. In the fabrication process in accordance with the present embodiment, a nickel vanadium (NiV) alloy is used as the conductive seed layer 462 due to the fact that NiV does not oxidize in air and eases the delamination process. the conductive seed layer 462 (NiV) is sputtered followed by the electroforming process to form the thick nickel inserts. The delamination of the Ni insert is to etch away the polycarbonate template via dichloromethane solvent. The deposition of the NiV seed layer 462 on the patterned wafer 404 is optimally done by DC magnetron sputtering at 100 Watts with 10 sccm of Argon gas until approximately 30 nm of NiV is deposited.

The nickel electroforming can be performed, for example, in a Technotras AG RD200 plating system containing a nickel sulfamate bath with sodium-dodecyl-ether-sulphamate as the wetting agent without organic additives. The composition of the bath optimally includes 89±3 g/l of pure Ni^{2±}, i.e., 380±10 g/l nickel sulfamate, NiCl₂-10 g/l, 40 g/l boric acid as a buffer and an approximately 0.06 g/l of an anion active wetting agent. The temperature of the bath is optimally held at above 50° C. In electrodeposition in accordance with the present embodiment, a low current should be maintained to ensure a certain degree of high hardness.

After nickel electroforming, the PC template 404 was completely dissolved by soaking in dichloromethane (DCM—CH₂Cl₂), thus retaining the structural fidelity of the hierarchical structures 464. Lastly, the nickel mold is preferably sputtered with a metal such as iridium to impart additional hardness to the insert. The final insert is then trimmed into the required size and dimensions as required to be fitted into the injection molding jig.

FIGS. 5A and 5B depict a SEM top planar view 500 and a SEM tilted view 550 of the final nickel insert with anti-reflection structures 464 fabricated in accordance with the present embodiment. The SEM images 500, 550 depict nickel inserts containing anti-reflection moth's eye structures 464 consisting of closely packed hexagonally arrayed 250 nm cone structures with a thin layer of iridium coated on top.

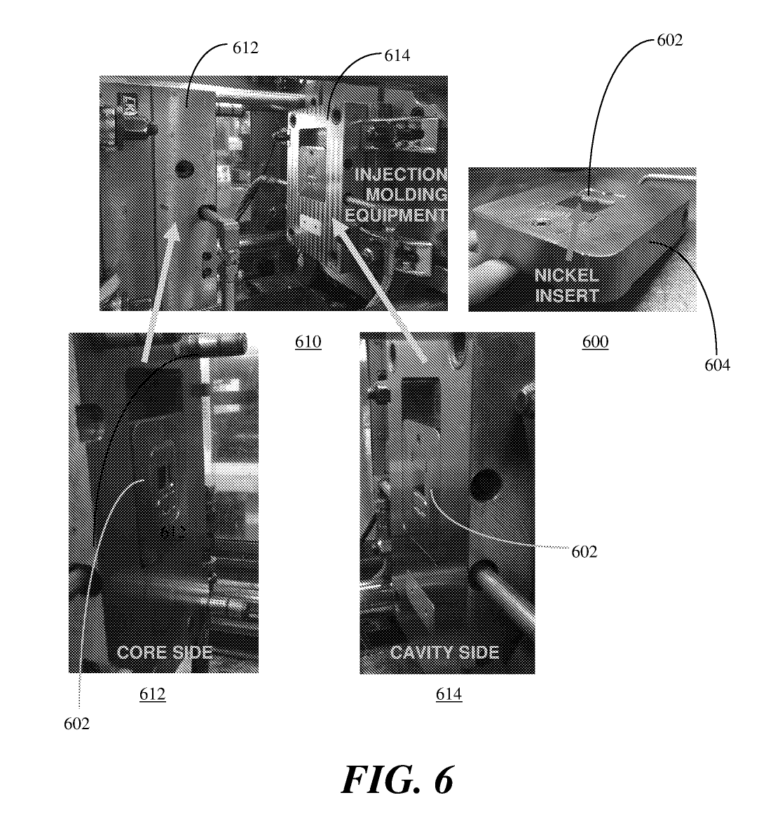

Referring to FIG. 6, views 600, 610, 612, 614 depict dual nickel inserts 602 fabricated in accordance with the present embodiment and mounted in molding jigs 604 for molding operations. The replicated nickel inserts 602 containing micro- and nanostructures can be incorporated into a steel insert platform of the molding jig 604 by using a hidden magnetic disc that firmly holds the inserts 602 in the steel platform. The thickness of the insert 602 can be varied according to the requirement of the process and can be tailored very precisely into an existing tooling jig 604 by means of wire cutting. The view 600 shows the nickel inserts being mounted onto the steel jig 604 and the views 610, 612, 614 depict dual nickel inserts 602 mounted on a core side 612 and a cavity side 614 of the molding jig 604.

Using a hybrid nickel-iridium insert 602 containing anti-reflective nanostructures, up to three hundred and fifty shots of an antireflective screen suitable for use in a walkie-talkie set has been experimentally shown, thereby proving modifying injection molding inserts with a nanoimprint template fabricated in accordance with the present embodiment can yield a hybrid insert capable of carrying out nanoinjection molding to transfer high resolution features (<200 nm) onto injection molded free-form three-dimensional products for scalable noninjection molding.

The nanoinjection molding process in accordance with the present embodiment is controlled by four main parameters. These parameters will ultimately determine whether a good filling of the molten polymer can be achieved. A good filling will yield good replication of the inserts. The four parameters are (a) temperature of the polymer melt, (b) injection pressure, (c) injection speed, and lastly (d) holding time required for the polymer melt to fill up the structures before the polymer is allowed to cool down. As the mold insert in accordance with the present embodiment is made from nickel, an optimal injection molding condition is a condition that is not too harsh that it will degrade and shorten the lifetime of the metal insert. In accordance with the present embodiment, an optimal process window is defined by the injection pressure and the injection speed being less than 100 MPa and 100 mm/second, respectively, thereby preserving the lifespan of the nickel inserts.

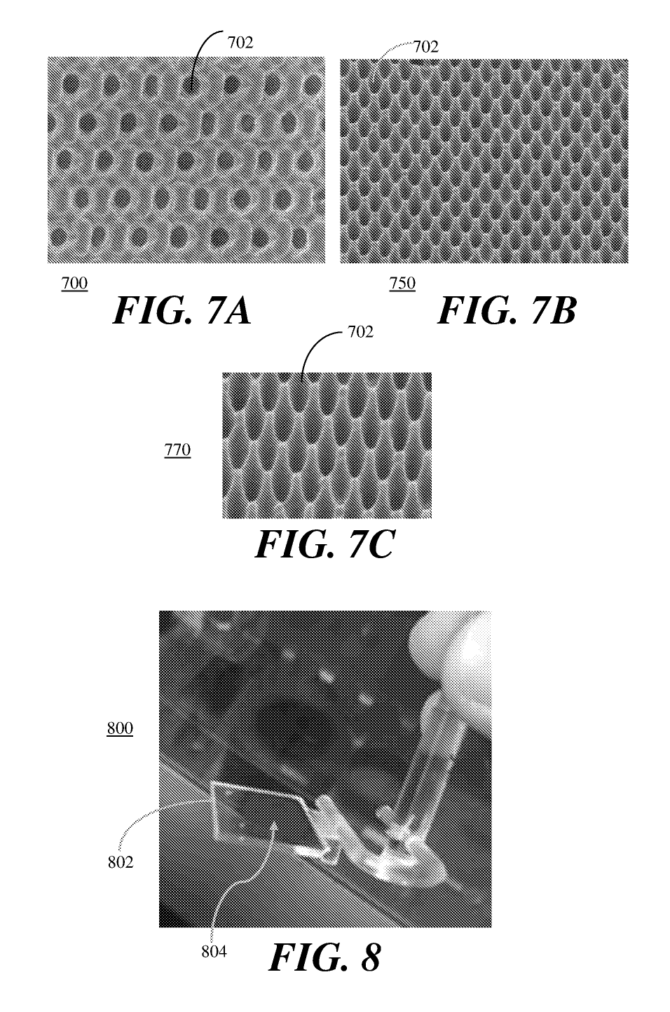

FIG. 7, comprising FIGS. 7A, 7B and 7C, depicts SEM views 700, 750, 780 of injection molded anti-reflection structures 702 molding using nickel inserts fabricated in accordance with the present embodiment. The SEM views 700, 750, 780 depict the well-defined structures achievable in accordance with the fabrication process of the present embodiment at optimized injection molding conditions of 320° C. polymer melt temperature, injection pressure of 100 MPa, injection speed of 75 mm/second and a longer holding time of 16 seconds for a polycarbonate feed.

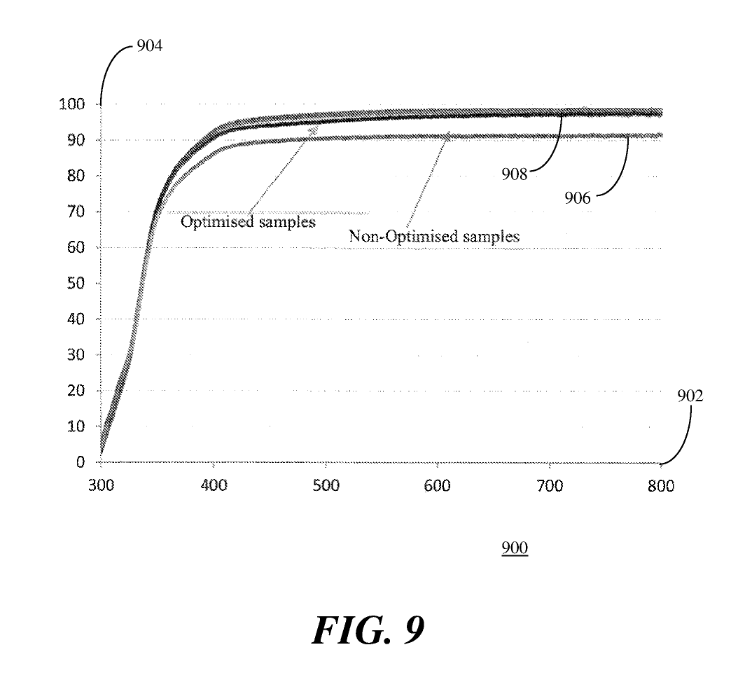

FIG. 8 depicts a view 800 of visual inspection of the injection molded anti-reflection structures 702 in accordance with the present embodiment. Visual inspection of the injection molded sample with a lens 802 revealed that the anti-reflection structures 702 displayed a deeper blue color 804 when viewed at slightly oblique angles (such as in the views 750, 780) which suggests that the anti-reflection structures 702 have been reproduced faithfully from the inserts. The lens 802 will display the deep blue color 804 when viewed at an oblique angle because the anti reflective structures are a 200 nm densely packed array of cone structures and will, accordingly, display a color at the 200 nm spectrum wavelength (i.e., deep blue).

Referring to FIG. 9 a graph 900 depicts transmissive properties of injection molded lenses prepared at various experimental conditions in accordance with the present embodiment. Wavelength is plotted along the x-axis 902 and percent light transmission is plotted along the y-axis 904. The molded samples were randomly chosen for the transmission test. As a comparison, another sample was also chosen from a non-optimized process run. The non-optimized sample refers to an injection molding run where the polymer filling of the anti-reflective structure was not complete. The results of the non-optimized samples 906 and the optimized samples 908 show a distinct difference between the two types of samples. An injection molded lens with a good replica of anti-reflection structures displays higher transmission level with improvement at around 5% within the visible light spectrum. For a lens with double-sided anti-reflection structures, we would expect the transmission to go as high as 99%.

Thus, it can be seen that the present embodiment provides a method of fabricating injection mold inserts that yields nanoscale surface textures onto the injection-molded products and which can provide a highly scalable nanoinjection fabrication method. Nanoinjection molding in accordance with the present embodiment can be used for the molding of various products where micro and nanostructuring are required for the generation of specific functionalities. Examples include optical lens or helmet visors, which have either one or both sides covered with an array of nanometer cone structures that can greatly enhance the functionality by providing high clarity, anti-ultraviolet (UV) transmission and superior anti-glare.

While exemplary embodiments have been presented in the foregoing detailed description of the invention, it should be appreciated that a vast number of variations exist. It should further be appreciated that the exemplary embodiments are only examples, and are not intended to limit the scope, applicability, operation, or configuration of the invention in any way. Rather, the foregoing detailed description will provide those skilled in the art with a convenient road map for implementing an exemplary embodiment of the invention, it being understood that various changes may be made in the function and arrangement of steps and method of operation described in the exemplary embodiment without departing from the scope of the invention as set forth in the appended claims.

1. A method of making an injection mold insert with hierarchical structures comprising:
imprinting a primary imprint structure on an article;
imprinting a secondary imprint structure on the primary imprint structure on the article, the secondary imprint structure comprising a plurality of shapes, each of the plurality of shapes being substantially smaller than shapes of the primary imprint structure;
bonding the article to a substrate;
sputter-coating the article with a metal film as an electroforming seed layer;
electroforming the injection mold insert over the article; and
dissolving the article to define the injection mold insert having a negative replica of the primary and secondary imprint structures.

2. The method in accordance with claim 1, wherein the steps of imprinting the primary and secondary imprint structures comprise imprinting one or more micro-sized or nano-sized imprint structures.

3. The method in accordance with claim 1, wherein the step of imprinting the primary imprint structure comprises imprinting the primary imprint structure on a polymer film.

4. The method in accordance with claim 1, wherein the first imprinting step comprises imprinting the primary imprint structure on the article at a temperature of 175 to 185° C. and a pressure of 35 to 50 bar for 300 to 500 seconds.

5. The method in accordance with claim 1, wherein the second imprinting step comprises imprinting the secondary imprint structure on the primary imprint structure on the article at a temperature of 145 to 160° C. and a pressure of 20 to 30 bar for 300 to 400 seconds.

6. The method in accordance with claim 1, wherein the step of bonding the article to the substrate comprises bonding the article to the substrate using an epoxy-based bonding agent.

7. The method in accordance with claim 6, wherein the step of bonding the article to the substrate using the bonding agent comprises bonding the article to the substrate using a spin-coated epoxy-based photoresist SU-8 bonding agent.

8. The method in accordance with claim 1, wherein the step of sputter-coating comprises sputter-coating the article with a nickel vanadium (NiV) alloy as the electroforming seed layer.

9. The method in accordance with claim 1, wherein the step of sputter-coating comprises sputter-coating the article with the electroforming seed layer to a thickness of 20 to 30 nm.

10. The method in accordance with claim 1, wherein the step of electroforming comprises electroforming the injection mold insert in a nickel sulfamate bath.

11. The method in accordance with claim 1, wherein the step of dissolving the article comprises dissolving the article in a solvent comprising dichloromethane (CH₂Cl₂).

12. The method in accordance with claim 1, further comprising the step of imprinting a tertiary imprint structure on the secondary imprint structure, the tertiary imprint structure comprising a plurality of shapes, each of the plurality of shapes being substantially smaller than shapes of the primary imprint structure.

13. The method in accordance with claim 1, further comprising the step of imprinting a tertiary imprint structure on the secondary imprint structure, the tertiary imprint structure comprising a plurality of shapes, each of the plurality of shapes being substantially smaller than shapes of the secondary imprint structure.

14. The method in accordance with claim 1, further comprising the step of sputter-coating the injection mold insert with metals or metal oxides.

15. The method in accordance with claim 1, further comprising the step of atomic layer depositing the injection mold insert with metals or metal oxides.

16. The method in accordance with claim 14, wherein the step of sputter-coating the injection mold insert comprises sputter-coating the injection mold insert with metals comprising iridium, tungsten or metal oxides.

17. The method in accordance with claim 15, wherein the step of atomic layer depositing the injection mold insert comprises atomic layer depositing the injection mold insert with metals comprising iridium, tungsten or with metal oxides.

18. The method in accordance with claim 1, further comprising depositing fluorinated or non-fluorinated diamond-like carbon films on the injection mold insert via a gaseous deposition process.

19. A product fabricated in accordance with a method of making an injection mold insert with hierarchical structures comprising:
imprinting a primary imprint structure on an article;
imprinting a secondary imprint structure on the primary imprint structure on the article, the secondary imprint structure comprising a plurality of shapes, each of the plurality of shapes being substantially smaller than shapes of the primary imprint structure;
bonding the article to a substrate;
sputter-coating the article with a metal film as an electroforming seed layer;
electroforming the injection mold insert over the article; and
dissolving the article to define the injection mold insert having a negative replica of the primary and secondary imprint structures.

20. The product in accordance with claim 19 wherein the product comprises an injection mold insert fabricated in accordance with the method of making an injection mold insert with hierarchical structures comprising:
imprinting a primary imprint structure on an article;
imprinting a secondary imprint structure on the primary imprint structure on the article, the secondary imprint structure comprising a plurality of shapes, each of the plurality of shapes being substantially smaller than shapes of the primary imprint structure;
bonding the article to a substrate;
sputter-coating the article with a metal film as an electroforming seed layer;
electroforming the injection mold insert over the article; and
dissolving the article to define the injection mold insert having a negative replica of the primary and secondary imprint structures.
